(19) United States
(12) Patent Application Publication
(10) Pub. No.: US 2022/0243323 A1
(43) Pub. Date: Aug. 4, 2022

(54) USE OF ROTATION TO CORRECT FOR AZIMUTHAL NON-UNIFORMITIES IN SEMICONDUCTOR SUBSTRATE PROCESSING

(71) Applicant: LAM RESEARCH CORPORATION, Fremont, CA (US)

(72) Inventors: Ramesh CHANDRASEKHARAN, Lake Oswego, OR (US); Seshasayee VARADARAJAN, Lake Oswego, OR (US); Pulkit AGARWAL, Beaverton, OR (US); Ravi KUMAR, Beaverton, OR (US); Adrien LAVOIE, Newberg, OR (US); Marcus CARBERY, Dublin (IE); Michael Philip ROBERTS, Tigard, OR (US)

(21) Appl. No.: 17/620,201

(22) PCT Filed: Jun. 16, 2020
(86) PCT No.: PCT/US2020/037843

§ 371 Date: Dec. 17, 2021

Related U.S. Application Data
(60) Provisional application No. 62/864,127, filed on Jun. 20, 2019.

(51) Int. Cl. C23C 16/458; H05B 1/02

(52) U.S. Cl. CPC C23C 16/4584; C23C 16/45527; H05B 1/0233; C23C 16/4586

(57) ABSTRACT

A substrate processing system includes a substrate support and a controller. The substrate support includes a lift pad, a plurality of zones, and a plurality of resistive heaters arranged throughout the plurality of zones. The plurality of resistive heaters includes separately-controllable resistive heaters arranged in respective ones of the plurality of zones. The controller is configured to determine a rotational position of a substrate arranged on the lift pad, selectively rotate the lift pad to adjust the substrate to the rotational position, and control the plurality of resistive heaters to selectively adjust temperatures within the plurality of zones based on the rotational position.

### CROSS-REFERENCE TO RELATED APPLICATIONS

This application claims the benefit of U.S. Provisional Application No. 62/864,127, filed on Jun. 20, 2019. The entire disclosure of the application referenced above is incorporated herein by reference.

### FIELD

The present disclosure relates to compensating for non-uniformities in semiconductor substrate processing systems and methods.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, photoresist removal, etc. During processing, the substrate is arranged on a substrate support such as an electrostatic chuck and one or more process gases may be introduced into the processing chamber.

The one or more processing gases may be delivered by a gas delivery system to the processing chamber. In some examples, deposition processes such as chemical vapor deposition (CVD), plasma enhanced CVD (PECVD), atomic layer deposition (ALD), etc. are used to deposit material on a substrate. In other examples, chemical and/or plasma enhanced processes are used to etch a substrate. Various alternating etching and deposition cycles may be performed on a same substrate.

### SUMMARY

A substrate processing system includes a substrate support and a controller. The substrate support includes a lift pad, a plurality of zones, and a plurality of resistive heaters arranged throughout the plurality of zones. The plurality of resistive heaters includes separately-controllable resistive heaters arranged in respective ones of the plurality of zones. The controller is configured to determine a rotational position of a substrate arranged on the lift pad, selectively rotate the lift pad to adjust the substrate to the rotational position, and control the plurality of resistive heaters to selectively adjust temperatures within the plurality of zones based on the rotational position.

In other features, the controller is configured to determine the rotational position based on data indicating azimuthal characteristics of at least one of the substrate, the substrate support, and a processing step to be performed on the substrate. The characteristics of the substrate include characteristics of the substrate associated with a previous processing step performed on the substrate. The data includes measurements of the substrate subsequent to a previous processing step performed on the substrate. The controller is configured to rotate the lift pad to each of a plurality of predetermined positions during a processing step performed on the substrate.

In other features, the controller is configured to control the plurality of resistive heaters to selectively adjust the temperatures within the plurality of zones in response to the rotational position being adjusted. The controller is configured to rotate the lift pad to adjust the substrate to the rotational position based on an arrangement of the plurality of zones. The controller is configured to rotate the lift pad prior to a trim processing step performed on the substrate. The controller is configured to rotate the lift pad during a trim processing step performed on the substrate.

A method of operating a substrate support including a lift pad, a plurality of zones, and a plurality of resistive heaters arranged throughout the plurality of zones including separately-controllable resistive heaters arranged in respective ones of the plurality of zones includes determining a rotational position of a substrate arranged on the lift pad, selectively rotating the lift pad to adjust the substrate to the rotational position, and controlling the plurality of resistive heaters to selectively adjust temperatures within the plurality of zones based on the rotational position.

In other features, the method includes determining the rotational position based on data indicating azimuthal characteristics of at least one of the substrate, the substrate support, and a processing step to be performed on the substrate. The characteristics of the substrate include characteristics of the substrate associated with a previous processing step performed on the substrate. The data includes measurements of the substrate subsequent to a previous processing step performed on the substrate. The method further includes rotating the lift pad to each of a plurality of predetermined positions during a processing step performed on the substrate.

In other features, the method further includes controlling the plurality of resistive heaters to selectively adjust the temperatures within the plurality of zones in response to the rotational position being adjusted. The method further includes rotating the lift pad to adjust the substrate to the rotational position based on an arrangement of the plurality of zones. The method further includes rotating the lift pad prior to a trim processing step performed on the substrate. The method further includes rotating the lift pad during a trim processing step performed on the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example substrate processing system according to the present disclosure;

FIG. 1B shows example heater zones of a substrate support according to the present disclosure;

FIGS. 2A-2C show example deposition thickness non-uniformity profiles according to the present disclosure;

FIGS. 2D, 2E, and 2F show other example heater zone arrangements according to the present disclosure;

FIGS. 3A, 3B, and 3C show a plan view of an example substrate support and substrate according to the present disclosure;

FIGS. 4A through 4D illustrate an example trim step according to the present disclosure;

FIGS. 5A, 5B, and 5C illustrate example profiles of measured features of a substrate according to the present disclosure;

FIG. 6 is a functional block diagram of an example controller configured to rotate a substrate according to the present disclosure; and

FIG. 7 illustrates steps of an example method for rotating a substrate to compensate for azimuthal non-uniformities according to the present disclosure.

In the drawings, reference numbers may be reused to identify similar and/or identical elements.

### DETAILED DESCRIPTION

In film deposition processes such as atomic layer deposition (ALD), various properties of the deposited film vary across a spatial (i.e., x-y coordinates of a horizontal plane) distribution. For example, substrate processing tools may have respective specifications for film thickness non-uniformity (NU), which may be measured as a full-range, a half-range, and/or a standard deviation of a measurement set taken at predetermined locations on a surface of a semiconductor substrate. In some example, the NU may be reduced either by, for example, addressing a direct cause of the NU and/or introducing a counteracting NU to compensate and cancel the existing NU. In other examples, material may be intentionally deposited and/or removed non-uniformly to compensate for known non-uniformities at other (e.g. previous or subsequent) steps in a process. In these examples, a predetermined non-uniform deposition/removal profile may be calculated and used.

Various properties of deposited ALD films may be influenced by a temperature of the substrate during deposition. In some examples, a temperature distribution may be adjusted to reduce thickness NU. For example, the temperature distribution may be adjusted to compensate for a known NU of a particular substrate processing tool (which may be referred to as profile compensation), to generate a predetermined NU profile for use during a particular process (which may be referred to as profile tuning), etc.

For example, during an ALD process (e.g., deposition of an oxide film), a substrate is arranged on a substrate support such as an ALD pedestal. Typically, an ALD pedestal comprises a single zone. An ALD pedestal may include a multi-zone (e.g., from 2 to 20 or more zones) heater layer. The heater layer may be embedded within an upper layer of the pedestal. For example, the heater layer may comprise a polyimide and silicone heater layer that is at least partially enclosed in an aluminum upper layer (e.g., an upper layer configured to support/contact the substrate arranged on the substrate support). In this example, the arrangement of the aluminum upper layer may function as a Faraday cage. In other examples, the upper layer may be a ceramic layer (e.g., Al₂O₃, AlN, etc.). Each zone of the heater layer controls a temperature of a respective zone of the pedestal. The upper layer is arranged on a base (e.g., a baseplate) of the pedestal and heat may be transferred from the upper layer to the baseplate, which may be cooled.

An arrangement (e.g., quantity, shape, geometry, etc.) of the zones may be configured to compensate for known film thickness NUs resulting from an ALD process. The zones may include, but are not limited to: two or more radial (i.e., annular) zones having different widths; two or more segmented radial zones (i.e., radial zones including multiple segments/azimuthal zones); an outer radial zone that is adjacent to and/or overlaps an edge of the substrate; and an outer radial zone arranged to adjust a temperature of a carrier ring (e.g. to control/correct radial profiles for deposition and/or removal through trimming).

In one example, the zones include ten zones, including a central zone, an inner-mid radius zone, four outer-mid radius zones (i.e., an outer-mid radius zone comprising four segments), and four outer edge zones (i.e., an outer edge zone comprising four segments). In some examples, the radial zones may include more than four segments (e.g., eight or more). Further, the azimuthal zones of adjacent radial zones may not be aligned. Instead, the azimuthal zones of one radial zone may have a different rotational orientation (i.e., clocking) relative to adjacent radial zones. Example systems and methods for using a pedestal having a multi-zone heater layer to adjust temperature distribution are described in more detail in in U.S. patent application Ser. No. 16/192,425, filed on Nov. 15, 2018, which is hereby incorporated herein in its entirety.

In some examples, the substrate support may include a lift pad (e.g., a centrally-located lift pad having a diameter less than a diameter of the substrate support). The lift pad is raised during substrate transfer and the substrate is placed onto the lift pad, which is subsequently lowered. In some examples (e.g., “twist pad” examples), the lift pad may be configured to rotate about a vertical center axis to adjust a rotational positon of the substrate. An example lift pad is described in more detail in U.S. Pub. No. 2018/0323098, published on Nov. 8, 2018, which is hereby incorporated herein in its entirety.

Systems and methods according to the present disclosure are further configured to rotate the lift pad while individually controlling temperatures of the respective zones to compensate for NUs. For example, the lift pad may be rotated to compensate for NUs resulting from previous processing steps (e.g., critical dimension NUs subsequent to lithographic etching of a photoresist layer and/or NU contributions from other trim or deposition steps). In one example, the lift pad may be rotated during a processing step to average out NU contributions across respective regions of the substrate. For example, NUs caused by a trim step may be corrected by rotating the lift pad during a subsequent deposition step.

In another example, some zones or regions of a zone (e.g., azimuthal regions) of the pedestal may have known or expected temperature NUs. In other words, an azimuthal region may have a range of temperature NUs. The lift pad may be rotated to average out the temperature NUs across the azimuthal region. In other examples, the lift pad may simply be rotated to a specific angular position to align an incoming substrate in accordance with known or expected features of the substrate for subsequent processing steps. In still other examples, rotation of the lift pad can be used to increase the number of the effective zones of the pedestal. For example, if the pedestal includes a single outer edge zone, rotating the lift pad to N (e.g., 4) different positions effectively establishes N different zones in the outer edge zone.

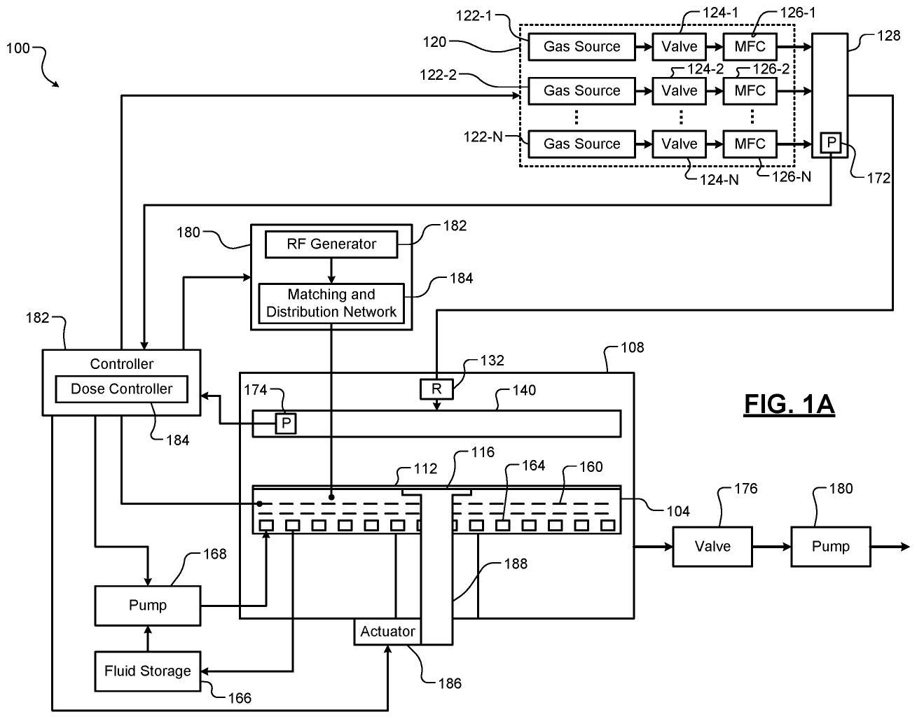

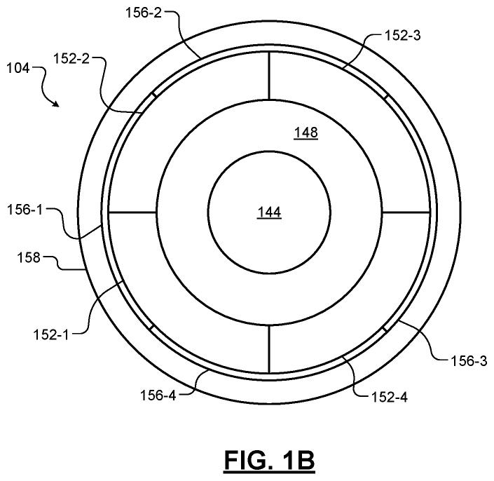

Referring now to FIGS. 1A and 1B, an example substrate processing system 100 including a substrate support 104 according to the principles of the present disclosure is shown. The substrate support (e.g., an ALD pedestal) 104 is arranged within a processing chamber 108. A substrate 112 is arranged on the substrate support 104 for processing. For example, processing including deposition and etching steps may be performed on the substrate 112. The substrate support 104 may include a lift mechanism, such as a lift pad 116, configured to be raised and lowered during transfer of the substrate 112 to the substrate support 104. The lift pad 116 according to the present disclosure may be further configured to be rotated as described below in more detail.

A gas delivery system 120 is configured to flow process gases into the processing chamber 108. For example, the gas delivery system 120 includes gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied via an optional pressure regulator 132 to a gas distribution device such as a multi-injector showerhead 140.

The substrate support 104 includes a plurality of zones. As shown in FIG. 1B, the substrate support 104 includes a central zone 144, an inner-mid radius zone 148, four outer-mid radius zones (i.e., an outer-mid radius zone 152 comprising four segments 152-1, 152-2, 152-3, and 152-4), and four outer edge zones (i.e., an outer edge zone 156 comprising four segments 156-1, 156-2, 156-3, and 156-4). The segments of the outer edge zone 156 are offset from (i.e., rotated with respect to) the segments of the outer-mid radius zone 152 (e.g., by 45°). In some examples, the substrate support 104 may include a second outer edge zone 158 radially outside of the outer edge zone 156. For example, an inner diameter of the second outer edge zone 158 may be greater than a diameter of the substrate 112. A temperature of the substrate support 104 may be controlled by using separately-controllable resistive heaters 160 arranged in respective ones of the zones.

The substrate support 104 may include coolant channels 164. Cooling fluid is supplied to the coolant channels 164 from a fluid storage 166 and a pump 168. Pressure sensors 172, 174 may be arranged in the manifold 128 or the showerhead 140, respectively, to measure pressure. A valve 176 and a pump 180 may be used to evacuate reactants from the processing chamber 108 and/or to control pressure within the processing chamber 108.

A controller 182 controls gas delivery from the gas delivery system 120. In some examples, the controller 182 may include a dose controller 184 that controls dosing provided by the multi-injector showerhead 140. The controller 182 controls pressure in the processing chamber and/or evacuation of reactants using the valve 176 and the pump 180. The controller 182 controls the temperature of the substrate support 104 and the substrate 112 based upon temperature feedback (e.g., from sensors (not shown) in the substrate support 104 and/or sensors (not shown) measuring coolant temperature).

The controller 182 according to the present disclosure is further configured to control rotation of the lift pad 116 while controlling the temperatures of the zones to compensate for NUs as described below in more detail. For example, the controller 182 may selectively raise, lower, and rotate the lift pad 116 (e.g., using an actuator 186 mechanically coupled to a shaft 188 of the lift pad 116).

In some examples, the substrate processing system 100 may be configured to perform etching (e.g., responsive to the controller 182) on the substrate 112 within the same processing chamber 108. Accordingly, the substrate processing system 100 may include an RF generating system 190 configured to generate and provide RF power (e.g., as a voltage source, current source, etc.) to one of a lower electrode (e.g., a baseplate of the substrate support 104, as shown) and an upper electrode (e.g., the showerhead 140). The other one of the lower electrode and the upper electrode may be DC grounded, AC grounded, or floating. For example only, the RF generating system 190 may include an RF generator 192 configured to generate an RF voltage that is fed by a matching and distribution network 194 to generate plasma within the processing chamber 108 to etch the substrate 112. In other examples, the plasma may be generated inductively or remotely. Although, as shown for example purposes, the RF generating system 190 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

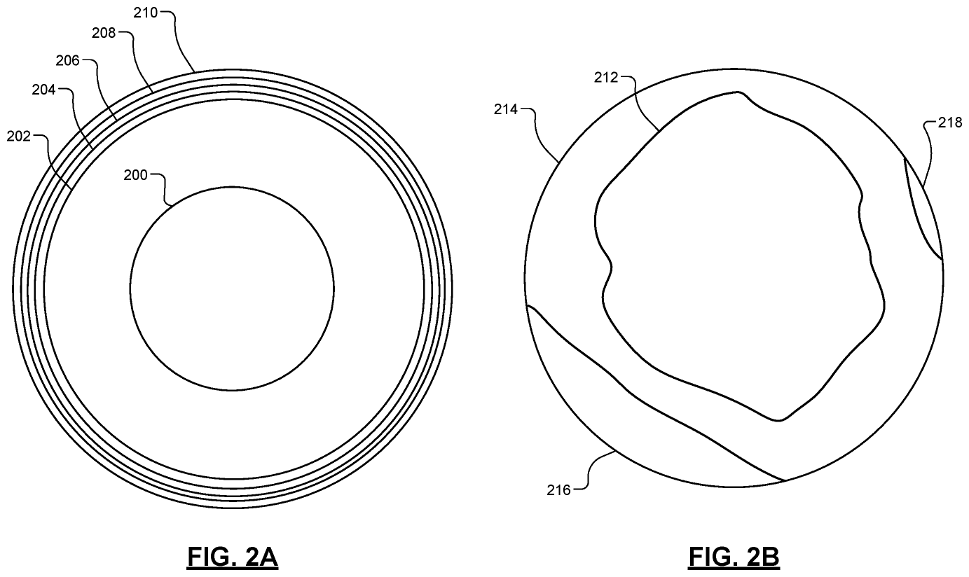

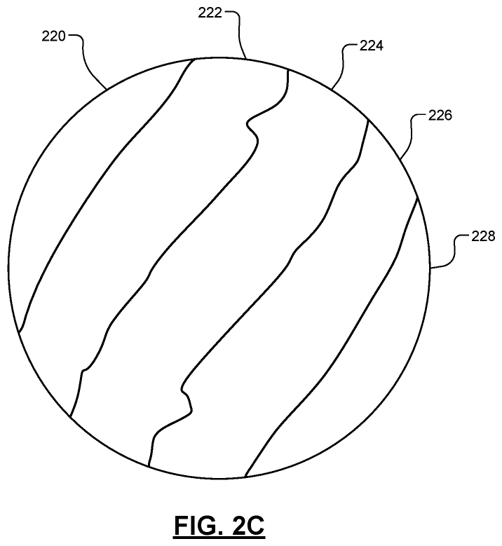

For example only, FIGS. 2A, 2B, and 2C show example deposition thickness NU profiles for different processes. For example, as shown in FIG. 2A, the thickness NUs are generally radial (e.g., the NUs may be generally dependent upon a distance from a center of the substrate and differ accordingly in regions 200, 202, 204, 206, 208, and 210). In other examples, the NUs may be both radial and azimuthal (e.g., in a rotational direction). For example, as shown in FIG. 2B, each of regions 212, 214, 216, and 218 may have different ranges of NUs. In still other examples, the NUs may be radial in only some directions. For example, as shown in FIG. 2C, each of regions 220, 222, 224, 226, and 228 may have different ranges of NUs. Further, in examples where the NUs are radial, the NUs may significantly increase in a narrow region at an outer edge of the substrate. Accordingly, two, three, or four uniform radial heater zones may not be able to compensate for all possible NU patterns.

The arrangement of the zones allows for compensation for both radial and azimuthal thickness NUs, as well as compensation for NUs at a narrow outer edge region of the substrate. For example only, FIGS. 2D, 2E, and 2F show other example zone arrangements. In other examples, the substrate support 104 may include other arrangements and combinations of radial and azimuthal zones. For example, the substrate support may 104 may include fewer (e.g., two) or more (e.g., 20 or more) zones, and each radial zone may be segmented into 2 to 8 or more separately controllable azimuthal zones to increase tunability.

The temperatures of the zones may be controlled according to a predetermined temperature control profile for a known NU profile. For example, one or more temperature control profiles may be stored (e.g., in the controller 182 and/or in memory accessible by the controller 182), input by a user, etc. Each of the temperature control profiles may be correlated to a predetermined NU profile (e.g., for a given process or recipe, processing chamber, etc.). According, during an ALD process, the heater zones may be individually controlled and adjusted to compensate for deposition NUs. The temperature control profiles correspond to target temperatures for each zone of the substrate support and may be calibrated according to expected temperature outputs of the zones for a given substrate support. In some examples, the temperature control profiles correlate a film property (e.g., thickness, deposition rate, etc.) and/or a temperature of the zone to one or more heater zone control parameters (e.g., duty cycle, percent output, etc.). Accordingly, a predetermined temperature control profile may be retrieved in accordance with a desired temperature distribution, film thickness, and/or other film property and the heater zones are controlled based on the heater zone control parameters in the retrieved temperature control profile.

Temperatures of respective heater zones may be controlled according to one or more types of feedback. In one example, each zone may include a respective temperature sensor. In another example, temperatures of each zone may be calculated. For example, a voltage and current of a resistive heater (e.g., using voltage and current sensors) may be measured to determine a resistance of the resistive heater. Since the resistance characteristics of the resistive heater are known, a temperature of the respective zone can be calculated based on a change in resistance caused by an associated change in temperature. In some examples, feedback may be provided using a combination of temperature sensors and calculations using other sensed or measured parameters such as voltage and current.

Individually controlling temperatures in different heater zones as described above may not be sufficient to compensate for all possible azimuthal variations and NUs across a substrate. For example, a substrate being processed may include azimuthal variations located within corresponding zones of the substrate support 104 (e.g., variations in deposition and/or etch amounts in previous processing steps performed on the substrate). Accordingly, simply adjusting temperatures of respective ones of the zones may not compensate for azimuthal variations on portions of the substrate within the zone. The controller 182 according to the present disclosure is configured to rotate the lift pad 116 to further compensate for the azimuthal variations.

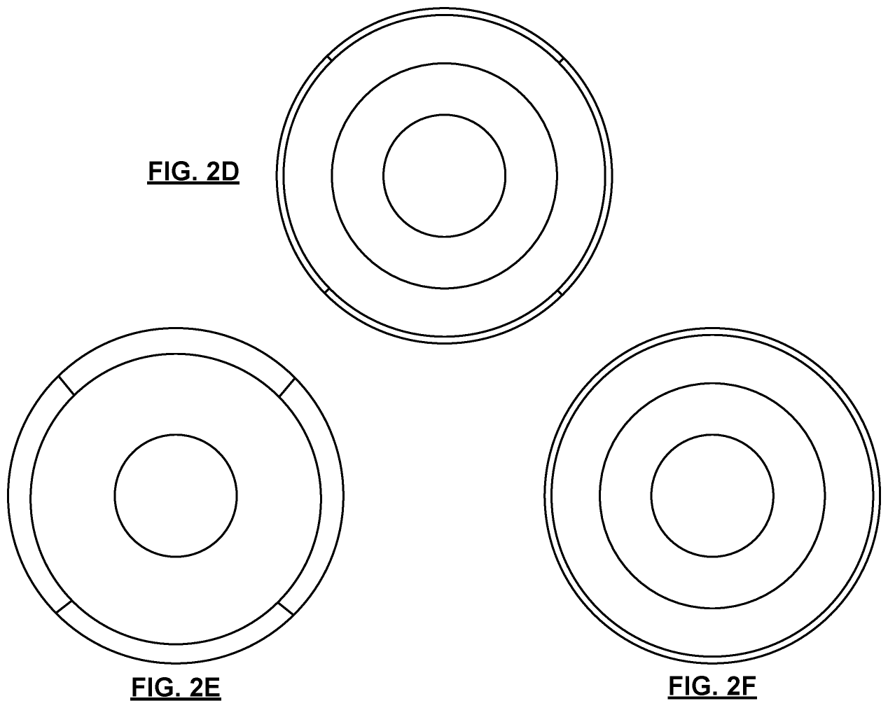

Referring now to FIGS. 3A, 3B, and 3C and with continued reference to FIGS. 1A and 1B, a plan view of an example substrate support 300 including a plurality of zones (numbered 1-10) is shown. A substrate 304 is shown supported on the substrate support 300 in FIGS. 3B and 3C. Each of the zones 1-10 may be individually controlled as described above. The substrate support 300 includes a lift pad 308 configured to be raised and lowered to facilitate transfer of the substrate 304 to and from the substrate support 300. Further, the lift pad 308 may be rotated to adjust a position (i.e., an angular position, rotational orientation, etc.) of the substrate 304 relative to the substrate support 300. Accordingly, the position of the substrate 304 relative to individual ones of the zones 1-10 may be adjusted by rotating the lift pad 308 (e.g., raising the lift pad 308, rotating the lift pad 308 to a different position, and lowering the lift pad 308).

In one example, the lift pad 308 may be rotated (e.g., through a plurality of fixed azimuthal positions) to average out NU contributions across respective regions of the substrate 304. For example, a processing step may be paused and the lift pad 308 is raised, rotated, and lowered prior to continuing the processing step. This rotation may be repeated throughout the processing step. In this manner, the effects of any azimuthal variations are distributed across the entire substrate 304 instead of being compounded in a single azimuthal region of the substrate 304.

Similarly, specific zones or regions of a zone (e.g., azimuthal regions) of the substrate support 300 may have known or expected temperature NUs. In other words, a specific one or more of the zones 1-10 of the substrate support 300 may have a range of temperature NUs that vary azimuthally. Accordingly, the lift pad 308 may be rotated to average out the temperature NUs across the corresponding azimuthal regions of the substrate 304 within the respective zones.

In each of the above examples, the lift pad 308 may be rotated only once or two or more times. For example, the lift pad 308 may be rotated between processing steps (e.g., to compensate, in a next processing step, for the effects of azimuthal NUs from a previous processing step) and/or one or times during a given processing step.

In other examples, the lift pad 308 may be rotated to a specific angular position to align the substrate 304 in accordance with known or expected features of the substrate 304 for subsequent processing steps. In other words, the substrate 304 may correspond to an incoming substrate that was transferred to the substrate support 300 subsequent to a previous deposition or etching step (e.g., in a different processing chamber). Features of the substrate 304 may have known or expected NUs caused by previous processing steps (e.g., based on metrology, modeling, and/or other measurement data). Accordingly, the lift pad 308 may be rotated to the specific angular position such that the subsequent processing step compensates for the NUs introduced by the previous processing step. For example, NUs caused by a previous trim step may be corrected by rotating the lift pad 308 during a subsequent deposition step. As a more specific example, the lift pad 308 may be rotated prior to a deposition step to compensate for critical dimension NUs resulting from etching performed on a photoresist layer.

In any of the above examples, the rotation of the lift pad 308 increases the number of the effective zones of the substrate support 300. For example, if the substrate support 300 includes ten zones 1-10 as shown in FIGS. 3A, 3B, and 3C, rotating the lift pad 308 to N different positions potentially increases the number of zones to as many as 10*N zones, depending on the degree of rotation between each position. In other examples, the effective number of zones may depend on the degree of rotation between each position and a specific configuration of the zones. The N positions may be uniformly or non-uniformly spaced.

FIGS. 3B and 3C show one example rotation between first and second positions, respectively. In this example, the lift pad 308 is configured to rotate between eight different positions as indicated by positions of uniformly spaced dashed lines. For example, the eight positions are spaced 45 degrees apart. An orientation of the substrate 304 on the substrate support 300 is indicated by arrow 312. In FIG. 3B, the substrate 304 is shown in a first position relative to the substrate support 300. In FIG. 3C, the substrate 304 is shown in a second position (e.g., rotated clockwise 90 degrees from the first position) relative to the substrate support 300.

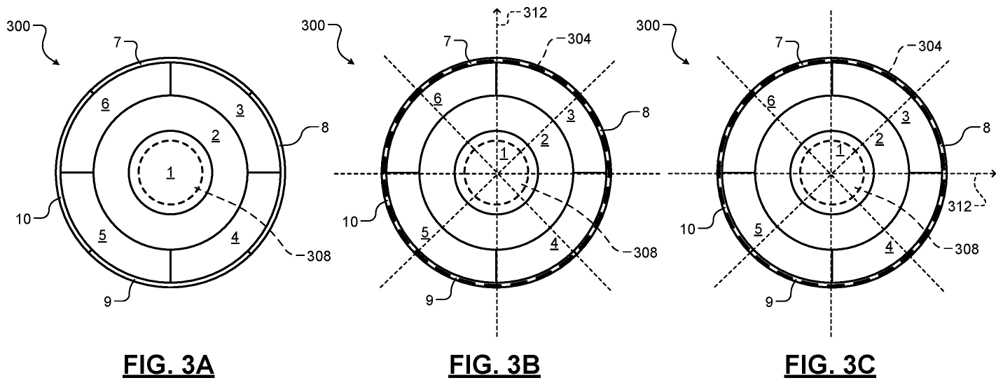

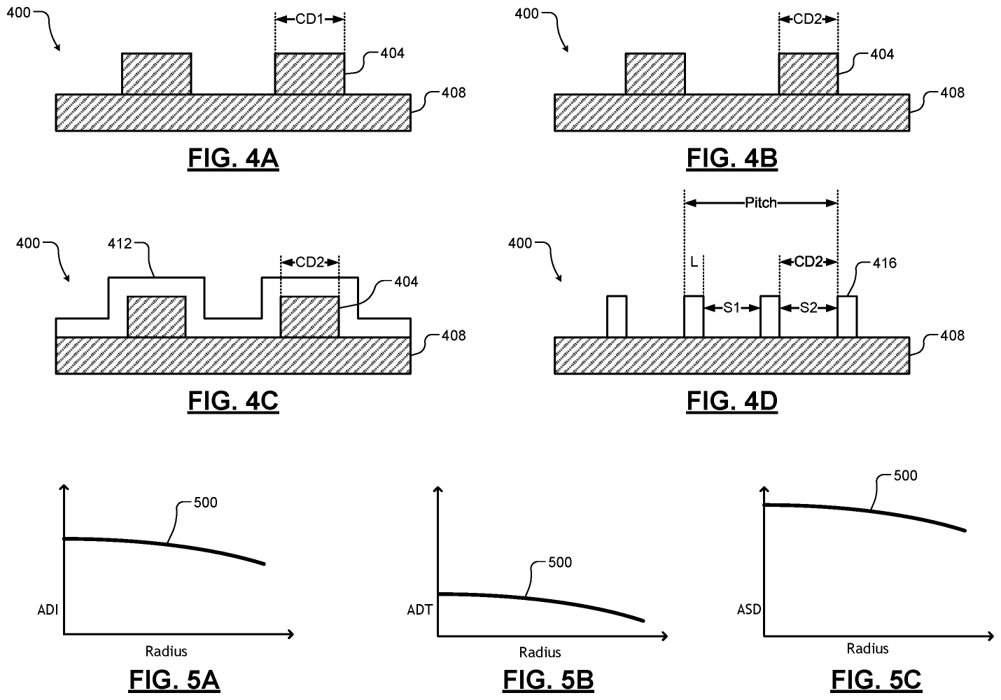

Steps of an example process (e.g., a self-aligned double patterning (SADP) process) that may be implemented with rotation of the lift pad 308 are described in FIGS. 4A, 4B, 4C, and 4D and with reference to FIGS. 5A, 5B, and 5C. For example only, the process is performed on a substrate 400 including mandrels 404 formed on a core layer 408. The mandrels 404 may correspond to a photoresist layer. In FIG. 4A, the mandrels 404 are shown prior to a trim step (e.g., subsequent to an etching step to form the mandrels 404 on the core layer 408). A width of the mandrels 404 corresponds to a critical dimension CD1. The mandrels 404 are trimmed (e.g., etched) as shown in FIG. 4B to adjust the width of the mandrels 404. Accordingly, the critical dimension of the mandrels 404 is reduced to CD2. In FIG. 4C, a spacer layer 412 is deposited (e.g., conformally deposited using ALD) over the core layer 408 and the mandrels 404.

FIG. 4D shows sidewall portions 416 of the spacer layer 412 remaining on the core layer 408 subsequent to performing one or more etch steps to remove portions of the spacer layer 412 and the mandrels 404. Spaces (e.g., S1, S2, etc.) between the sidewall portions 416 correspond to respective widths (e.g., CD2) of the mandrels 404. Accordingly, a pitch of the sidewall portions 416 may be defined as S1+S2+2L, where L corresponds to a line width (i.e., a width of one of the sidewall portions 416).

FIGS. 5A, 5B, and 5C show profiles 500 of measurements of widths of the mandrels 404 at various stages in the process described in FIGS. 4A-4D. The profiles 500 illustrate the measurements relative to a radius (e.g., a distance from a center) of the substrate 400. The profiles 500 may correspond to averages of measurements performed on a plurality of substrates, such as metrology data. As shown, the measurements decrease (i.e., the profiles 500 curve downward) as the radius increases. For example, as shown in FIG. 5A, the profile 500 illustrates an after dose (or “after develop”) inspection (ADI) measurement subsequent to a lithographic etch of a photoresist layer. In other words, the profile 500 shown in FIG. 5A corresponds to a width of the mandrels 404 prior to being trimmed as shown in FIG. 4A.

As shown in FIG. 5B, the profile 500 illustrates an after development and trim (ADT) measurement subsequent to trimming the photoresist layer. In other words, the profile 500 shown in FIG. 5B corresponds to a width of the mandrels 404 subsequent to being trimmed as shown in FIG. 4B.

As shown in FIG. 5C, the profile 500 illustrates an after spacer deposition (ASD) measurement subsequent to depositing a spacer on the photoresist layer. In other words, the profile 500 shown in FIG. 5C corresponds to a width of the mandrels 404 with the deposited spacer layer 512 as shown in FIG. 5C.

The radial variation of the profiles 500 may be generally retained between the stages shown in FIGS. 5A, 5B, and 5C. Accordingly, NUs associated with the radial variation may be predictable and correctable using various techniques including, but not limited to, temperature control of individual radial zones. Conversely, azimuthal variations may be correctable by rotating the lift pad 308 as described above. For example, the lift pad 308 may be rotated to adjust the position of the substrate 400 upon transfer (i.e., the position of an incoming substrate), between stages (e.g., subsequent to etching but prior to trim, subsequent to trim but prior to deposition of the spacer layer 412, etc.).

The position of the substrate 400 may be adjusted (e.g., to known fixed positions) based on known NUs associated with the process and/or the processing chamber, metrology data associated with incoming substrates, etc. In some examples, individual substrates may each be measured and the lift pad 308 can be rotated in accordance with the measurements for each specific substrate. In other examples, the substrate 400 may be rotated through a plurality of positions to average out NUs across azimuthal regions of the substrate 400. For example, for a given processing step, the substrate 400 may be adjusted to each of a plurality of different positions for a respective, predetermined portion of the processing step.

In one example, adjusting temperatures of individual zones and selectively rotating the substrate 400 may be used to adjust etching and deposition of mandrel patterns and associated spacer layers. For example, mandrels and spacer layers typically have an extremely thin profile. Accordingly, critical dimensions are more difficult to control, and relatively small process NUs may result in significant critical dimension NUs, such as spacer thickness NUs. The multi-zone heater layer can be used to compensate for various process NUs to improve spacer thickness uniformity, and temperatures may be controlled to tune critical dimensions of features across a surface of a substrate (i.e., regardless of whether there are process NUs). Further, the substrate 400 can be rotated to increase the effective number of zones, adjust the rotational position of the substrate 400 to a desired orientation relative to the zones, average out azimuthal variations within zones, etc. For example, if different portions of the substrate require different deposition thicknesses, temperatures of respective heater zones can be separately controlled to achieve the different deposition thicknesses across the substrate 400 while also rotating the substrate 400 into different positions for respective portions of a deposition step.

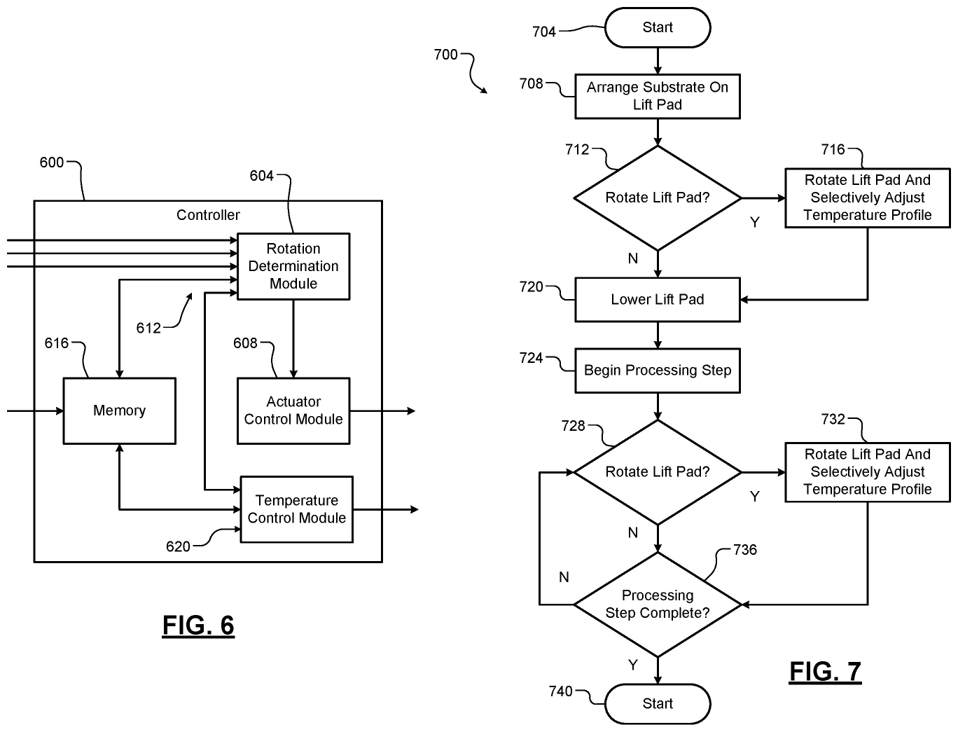

Referring now to FIG. 6, an example controller 600 (e.g., corresponding to the controller 182 of FIG. 1A) configured to rotate a substrate (e.g., the substrate 304) and individually control temperatures of respective zones of a substrate support (e.g., the substrate support 300) to compensate for azimuthal NUs according to the present disclosure is shown. The controller 600 includes a rotation determination module 604 and an actuator control module 608. The rotation determination module 604 is configured to determine when to rotate a lift pad (e.g., the lift pad 308) to adjust rotational positions of the substrate 304 and to determine the rotational positions. For example, the rotation determination module 604 receives data (e.g., via one or more inputs 612) indicative of characteristics of the substrate 304, the substrate support 300, the processing chamber (e.g., the processing chamber 108), etc. and determines one or more rotational positions of the substrate 304 based on the data.

For example, the data may include a rotation profile or model input to the controller 600 and/or stored in memory 616 and received by the rotation determination module 604. The rotation profile may indicate one or more fixed azimuthal positions, a specific time to rotate the substrate 304 to respective ones of the positions, period (i.e., an amount of time) for the substrate 304 to be maintained in each position, etc. Each of the positions may be correlated to a particular processing step. The data may further include user inputs (e.g., indicating specific positions and timing for rotation), inputs indicating known characteristics of the substrate 304, parameters (e.g., processing parameters as controlled, measured, sensed, modeled, etc.) from previous processing steps, etc.

The rotation determination module 604 controls the actuator control module 608 based on the data to rotate the lift pad 308 accordingly. In this manner, for a given processing step, the controller 600 controls rotation of the lift pad 308 to selectively rotate the substrate 304 to one or more rotational positions during respective processing steps.

The data may further include temperature data received from a temperature control module 620 configured to individually control temperatures of respective zones (e.g., respective ones of the zones 1-10 as shown in FIG. 3A). Conversely, the temperature control module 620 may adjust temperatures of the zones 1-10 in accordance with the rotational position of the substrate 304. For example, the temperature control module 620 may communicate with the rotation determination module 604 to determine the rotational position of the substrate 304 and adjust a temperature control profile accordingly. For example only, the temperature control module 620 may selectively adjust the temperature control profile each time the substrate 304 is rotated.

Referring now to FIG. 7, an example method 700 for rotating a substrate to compensate for azimuthal non-uniformities according to the present disclosure begins at 704. At 708, a substrate is arranged on a lift pad of a substrate support. At 712, the method 700 (e.g., the controller 600) determines whether to rotate the lift pad. For example, the controller 600 may determine whether to rotate the lift pad based on known features (e.g., known azimuthal NUs) of the substrate resulting from previous processing steps. If true, the method 700 continues to 716. If false, the method 700 continues to 720.

At 716, the method 700 (e.g., the controller 600) rotates the lift pad to adjust the rotational position of the substrate and selectively adjusts the temperature control profile according to the adjusted rotational position. In some examples, the temperature control profile may not need to be adjusted. For example, if the substrate is to be rotated multiple times to average out azimuthal variations, a same (e.g., fixed) temperature control profile may be maintained throughout the processing step. Similarly, if the substrate is rotated such that a known azimuthal variation is located in a zone having a desired temperature, adjustment of the temperature control profile may be unnecessary.

At 720, the method 700 (e.g., the controller 600) lowers the lift pad. At 724, the method 700 (e.g., the controller 600) begins a processing step. At 728, the method 700 (e.g., the controller 600) determines whether to rotate the lift pad to adjust the rotational position of the substrate. If true, the method 700 continues to 732. If false, the method 700 continues to 736. At 732, the method 700 (e.g., the controller 600) rotates the lift pad to adjust the substrate to a next rotational position selectively adjusts the temperature control profile according to the next rotational position. For example, rotating the lift pad may include pausing the processing step, raising, rotating, and lowering the lift pad, and restarting the processing step.

At 736, the method 700 (e.g., the controller 600) determines whether the processing step is complete. If true, the method 700 ends at 740. If false, the method 700 continues to 728 to continue the processing step.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, a controller and/or components thereof (e.g., modules) may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system, comprising:
a substrate support including
a lift pad,
a plurality of zones, and
a plurality of resistive heaters arranged throughout the plurality of zones, wherein the plurality of resistive heaters includes separately-controllable resistive heaters arranged in respective ones of the plurality of zones; and
a controller configured to
determine a rotational position of a substrate arranged on the lift pad,
selectively rotate the lift pad to adjust the substrate to the rotational position, and
control the plurality of resistive heaters to selectively adjust temperatures within the plurality of zones based on the rotational position.

2. The substrate processing system of claim 1, wherein the controller is configured to determine the rotational position based on data indicating azimuthal characteristics of at least one of the substrate, the substrate support, and a processing step to be performed on the substrate.

3. The substrate processing system of claim 2, wherein the characteristics of the substrate include characteristics of the substrate associated with a previous processing step performed on the substrate.

4. The substrate processing system of claim 2, wherein the data includes measurements of the substrate subsequent to a previous processing step performed on the substrate.

5. The substrate processing system of claim 1, wherein the controller is configured to rotate the lift pad to each of a plurality of predetermined positions during a processing step performed on the substrate.

6. The substrate processing system of claim 1, wherein the controller is configured to control the plurality of resistive heaters to selectively adjust the temperatures within the plurality of zones in response to the rotational position being adjusted.

7. The substrate processing system of claim 1, wherein the controller is configured to rotate the lift pad to adjust the substrate to the rotational position based on an arrangement of the plurality of zones.

8. The substrate processing system of claim 1, wherein the controller is configured to rotate the lift pad prior to a trim processing step performed on the substrate.

9. The substrate processing system of claim 1, wherein the controller is configured to rotate the lift pad during a trim processing step performed on the substrate.

10. A method of operating a substrate support including a lift pad, a plurality of zones, and a plurality of resistive heaters arranged throughout the plurality of zones, wherein the plurality of resistive heaters includes separately-controllable resistive heaters arranged in respective ones of the plurality of zones, the method comprising:
determining a rotational position of a substrate arranged on the lift pad;
selectively rotating the lift pad to adjust the substrate to the rotational position; and
controlling the plurality of resistive heaters to selectively adjust temperatures within the plurality of zones based on the rotational position.

11. The method of claim 10, further comprising determining the rotational position based on data indicating azimuthal characteristics of at least one of the substrate, the substrate support, and a processing step to be performed on the substrate.

12. The method of claim 11, wherein the characteristics of the substrate include characteristics of the substrate associated with a previous processing step performed on the substrate.

13. The method of claim 11, wherein the data includes measurements of the substrate subsequent to a previous processing step performed on the substrate.

14. The method of claim 10, further comprising rotating the lift pad to each of a plurality of predetermined positions during a processing step performed on the substrate.

15. The method of claim 10, further comprising controlling the plurality of resistive heaters to selectively adjust the temperatures within the plurality of zones in response to the rotational position being adjusted.

16. The method of claim 10, further comprising rotating the lift pad to adjust the substrate to the rotational position based on an arrangement of the plurality of zones.

17. The method of claim 10, further comprising rotating the lift pad prior to a trim processing step performed on the substrate.

18. The method of claim 10, further comprising rotating the lift pad during a trim processing step performed on the substrate.
